(19) United States
(12) Patent Application Publication
(10) Pub. No.: US 2009/0137068 A1
(43) Pub. Date: May 28, 2009

(54) Method and Computer Program Product for Wafer Manufacturing Process Abnormalities Detection

(76) Inventors: Michal Rosen-Zvi, Jerusalem (IL); Justin Wai-chow Wong, South Burlington, VT (US); Yiheng Xu, Hopewell Junction, NY (US); Elad Yom-Tov, Mizpe Hoshaya (IL)

Correspondence Address: IBM CORPORATION, T.J. WATSON RESEARCH CENTER, P.O. BOX 218, YORKTOWN HEIGHTS, NY, 10598, US

(21) Appl. No.: 11/946,064

(22) Filed: Nov. 28, 2007

(51) Int. Cl. H01L 21/66; G06F 17/50

(52) U.S. Cl. 438/14; 716/5; 257/E21.521

(57) ABSTRACT

A method for wafer manufacturing process abnormalities detection, the method includes: generating a classifier in response to compression based similarities between relevant wafer manufacturing process information of pairs of wafers; and utilizing the classifier to detect wafer manufacturing process abnormalities.

### FIELD OF THE INVENTION

The invention relates to methods and computer program products for wafer manufacturing process abnormalities detection.

### BACKGROUND OF THE INVENTION

Integrated circuits are very complex devices that include multiple layers. A layer can include conductive materials, isolating materials, semi-conductive materials or a combination thereof. These various materials are arranged in patterns, usually in accordance with the expected functionality of the integrated circuit. The patterns also reflect the manufacturing process of the integrated circuits.

These mentioned above layers are formed by passing a wafer through multiple manufacturing machines, each including one or more chambers (also known as process chambers or manufacturing chambers).

This highly complex manufacturing process is carefully monitored and diagnosed in order to detect wafer manufacturing process abnormalities. Various metrology, inspection and failure analysis techniques evolved for inspecting wafers during the fabrication stages or between consecutive manufacturing stages, either in combination with the manufacturing process (also termed “in line” inspection techniques) or not (also termed “off line” inspection techniques). In addition, various parameters of the manufacturing machines are also monitored. These parameters can include timing information, temperature, pressure and the like.

The mentioned above monitoring process generates huge amounts of varied information, much of which can be used to diagnose the state of the wafer manufacturing process. Such information (also known as wafer manufacturing process information) can include, for example, the temporal recordings of machine parameters such as temperature, pressure, etc, and event information such as start and stop operations.

There is a growing need to provide effective methods and computer program product for wafer manufacturing process abnormalities detection.

### SUMMARY

A method for wafer manufacturing process abnormalities detection, the method includes: generating a classifier in response to compression based similarities between relevant wafer manufacturing process information of pairs of wafers; and utilizing the classifier to detect wafer manufacturing process abnormalities.

### BRIEF DESCRIPTION OF THE DRAWINGS

The present invention will be understood and appreciated more fully from the following detailed description taken in conjunction with the drawings in which:

FIG. 1 illustrates a wafer manufacturing process abnormalities detection system and various machines according to an embodiment of the invention;

FIG. 2 illustrates twenty five mass spectrums obtained during a residual gas analysis process of a certain wafer;

FIG. 3 illustrates a matrix that includes compression based similarity results for these wafers of one hundred and seventy wafers according to an embodiment of the invention;

FIGS. 4 and 5 illustrate receiver operating characteristic of two classifiers according to an embodiment of the invention;

FIG. 6 illustrates relevant wafer manufacturing process information selected during different iterations of a progressive wafer manufacturing process abnormalities detection process according to an embodiment of the invention;

FIG. 7 illustrates areas below ROC curves obtained during each of iterations of a progressive wafer manufacturing process abnormalities detection process according to an embodiment of the invention;

FIG. 8 illustrates a conversion of timing information to relevant wafer manufacturing process information according to an embodiment of the invention;

FIG. 9 illustrates receiver operating characteristic of another classifier according to an embodiment of the invention; and

FIG. 10 illustrates a method for wafer manufacturing process abnormalities detection according to an embodiment of the invention.

### DETAILED DESCRIPTION OF THE DRAWINGS

A method and computer program product for wafer manufacturing process abnormalities detection are provided. The method includes: generating a classifier in response to compression based similarities between relevant wafer manufacturing process information of pairs of wafers; and utilizing the classifier to detect wafer manufacturing process abnormalities.

The term “wafer manufacturing process abnormalities” means abnormalities in a wafer manufacturing process. A wafer manufacturing process abnormality can include deviations from expected (or desired) manufacturing parameters such as temperature, duration or process, cleanliness level, and the like. A wafer manufacturing process abnormality can damage a wafer, can cause one or more wafer characteristics to change, can cause a wafer failure, and the like. It is noted that some wafer manufacturing process abnormality can be non-destructive. A wafer manufacturing process abnormality can affect the yield of the wafer manufacturing process but this is not necessarily so.

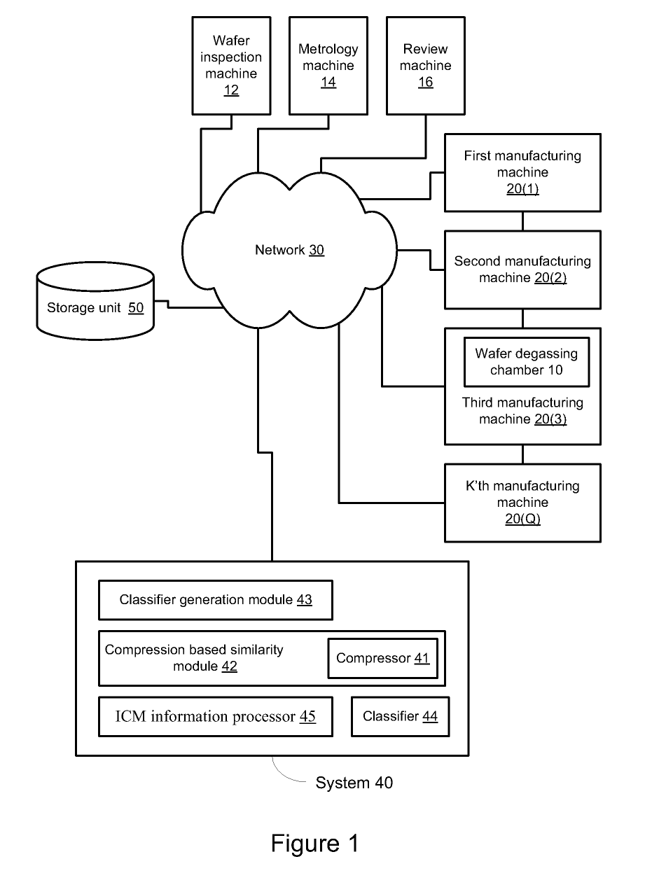

FIG. 1 illustrates wafer manufacturing process abnormalities detection system (system) 40 and various machines according to an embodiment of the invention.

System 40 is illustrated as being connected via network 30 to storage unit 50 and to multiple machines such as manufacturing machines 20(1), 20(2), 20(3) and 20(Q), and to multiple additional machines such as wafer inspection machine 12, metrology machine 14 and review machine 16. It is noted that other machines can be connected to system 40 and that system 40 can itself have a distributed architecture.

Wafer manufacturing process (WAP) information can be sent to storage unit 50 from any one of machines 12, 14, 16, 20(1), 20(2), 20(3) and 20(Q) or can be sent to system 40.

Each manufacturing machine out of manufacturing machines 20(1), 20(2), 20(3) and 20(Q) can include one or more chambers. Wafer manufacturing machine 20(3) is a film deposition tool and includes wafer degassing chamber 10.

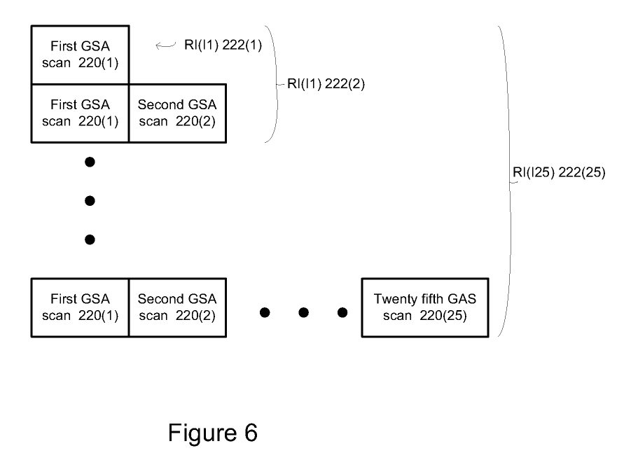

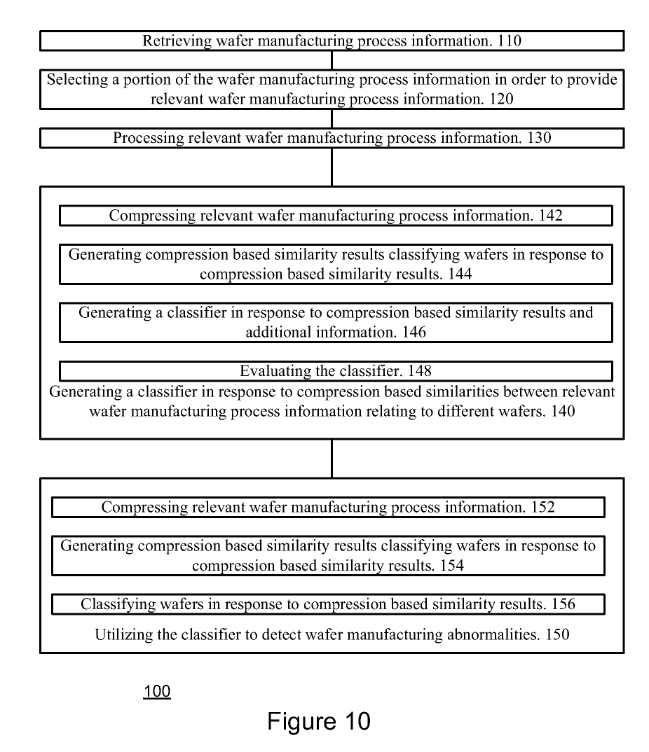

System 40 can retrieve WAP information and process it in order to detect WAP abnormalities. As will be illustrated in greater details in relation to FIGS. 6 and 10, system 40 can perform multiple iterations of a WAP abnormality detection process in order to detect WAP abnormalities and especially to perform root cause analysis.

System 40 can include software, hardware, firmware, middleware or a combination thereof. Conveniently, system 40 includes compression based similarity module 42, classifier generation module 43, classifier 44 and WAP information processor 45.

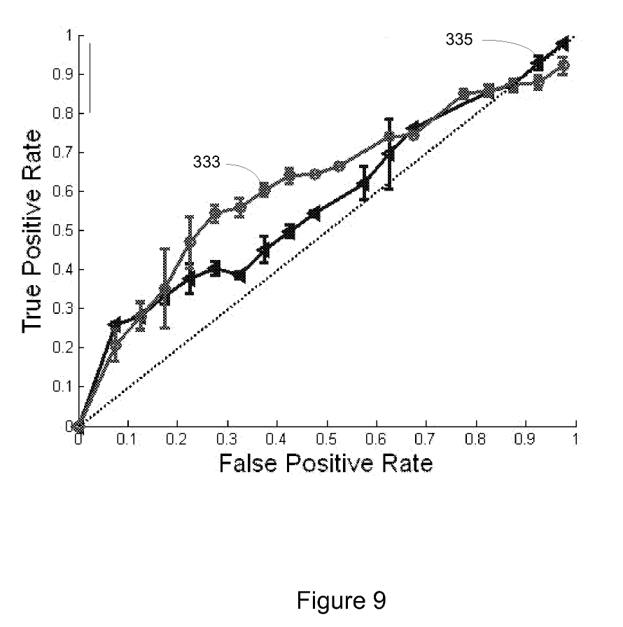

WAP processor 45 can process WAP information. The processing can include format conversion, as illustrated in FIG. 9, and can include de-quantizing, sampling, as well as one or more prior art processing stages.

System 40 can select (filter) only a portion of WAP information. The filtering can be implemented by retrieving only a portion of WAP information from storage unit 50 or by filtering WAP information after the WAP information was at least partially processed by WAP processor 45.

Relevant WAP information is sent to compression based similarity module 42. It is termed relevant because it is used by other modules of system 40 and not filtered out.

The relevant WAP information is compressed by compressor 41 that can be either included within compression based similarity module 42 (as illustrated in FIG. 1) or can be accessible by compression based similarity module 42.

Similarity module 42 generates compression based similarity results relating to different wafers.

Conveniently, similarity module 42 calculates the following equation:

$$similarity ( A , B ) = \frac{size ( AB ) - min ( size ( A ) , size ( B ) )}{max ( size ( A ) , size ( B ) )}$$

In this equation similarity (A,B) is the compression based similarity result (also referred to as a normalized compression distance between A and B), A and B are two non-compresses representations of information, size(A) is the size of a compressed representation of A, size(B) is the size of a compressed representation of B, AB is a non-compressed representation of a concatenation of A and B, and size(AB) is the size of a compressed representation of the concatenation of A and B. It is assumed that if A and B are similar, the overhead needed to compress B after compressing A is small.

This similarity equation was suggested in the following article: “Clustering by compression”, R. Cilibrasi and P. M. B. Vitanyi, IEEE transactions on information theory, Vol. 51, No. 4, April 2005, 1523-1545. This article describes a clustering method that is responsive to compression based similarity. It is noted that the compression based similarity was not previously applied to wafer manufacturing process, and neither was suggested for root cause analysis.

System 40 can conveniently operate at one out of two modes—a classifier generation mode and a classifier utilization mode. System 40 first generates a classifier and then can utilize it.

In both modes compression based similarity module 42 generates compression based similarity results relating to different wafers. When system 40 operates at a classifier generation mode it used this information to generate a classifier. When system 40 operates at a classifier utilization mode it uses this information to detect WAP abnormalities.

When operating at a classifier generation mode, compression based similarity module 42 sends compression based similarity results (of different wafers) to classifier generation module 43. Classifier generation module 43 also receives additional information such as functionality information. Functionality information is indicative of the functionality of each of the different wafers. A wafer can be classified as a defective (BAD) wafer or a functional (GOOD) wafer. The additional information can assist in differentiating between information relating to functional wafers and information relating to defective wafers.

Classifier generation module 43 can generate, in response to these compression based similarity results and in response to the additional information, classifier 44. Classifier generation module 43 can utilize one or more prior art classifier generation methods such as but not limited to support vector machine (SVM). It is noted that the classifier can be a binary classifier but this is not necessarily so. In general, since the classifier is trained using similarity measurements, classifiers which use kernel methods (such as SVM) are to be preferred. However, other classification methods may be used, by transforming the similarity matrix to a feature space. This can be done, for example by taking the largest eigenvectors of the similarity matrix.

Classifier generation module 43 can also evaluate classifier 44 by using one or more prior art classifier evaluation methods. The evaluation process can be responsive to the additional information and to the outcome of classifier 44.

During the classifier evaluation process classifier generator module 43 can compare the sensitivity versus specificity (equivalent to comparing the fraction of true positive rates to the fraction of false positive rate) of classifier 44. The comparison results can be graphically represented by the so-called receiver operating characteristic or ROC curve. Classifier evaluation methods typically measure the area below a ROC curve. Better classifiers are characterized by larger areas under their respective ROC curve.

After classifier 44 is generated, compression based similarity results can be fed to classifier 44 in order to detect WAP abnormalities.

The following examples will assist in understanding how system 40 operates.

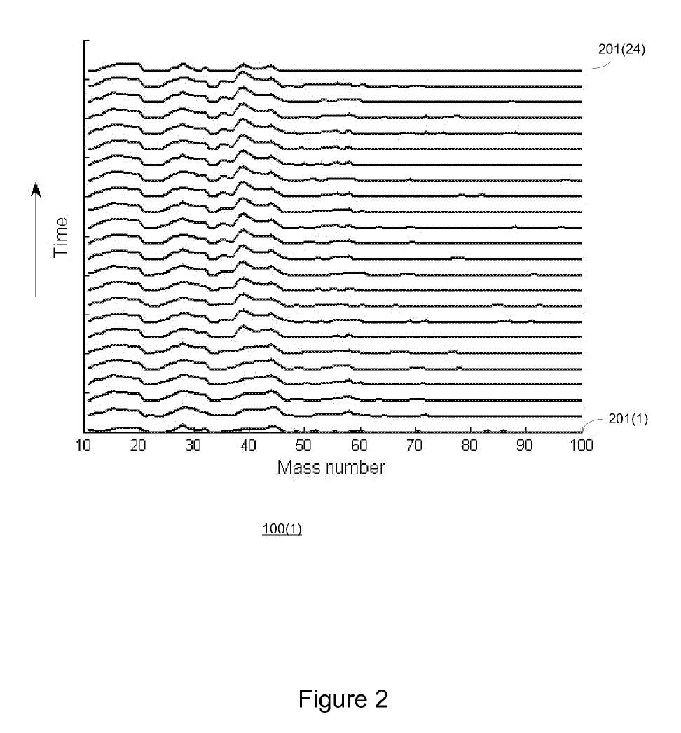

Wafer degassing (the degassing chamber) process is the first step of the film deposition process in which the wafer is heated up to vaporize foreign materials on the wafer prior to film deposition. A Residual Gas Analyzer (RGA) system attached to wafer degassing chamber 10 is used identify and quantify the possible contaminates. A mass spectrum (also refereed to as RGA scan) is obtained by the RGA system. The RGA scans are taken at regular intervals, for example, every 5 seconds. The intensity of each mass of the spectrum represents a concentration/partial pressure of its corresponding chemical specie. An abnormally high intensity measurement usually indicates contamination residue on the wafer, which causes higher than normal out-gassing. FIG. 2 illustrates twenty five mass spectrums 201(1)-201(25) obtained during a RGA process of a first wafer out of a group of two hundred and eleven wafers.

During two different WAP abnormality detection processes two groups of wafers were evaluated. One group of wafers included two hundred and eleven wafers (out of which eighty wafers were defective). Between nineteen and twenty five mass spectrums were obtained for each wafer.

Each mass spectrum was processed by sampling, logarithmically scaling and quantization. The results of a RGA process of each wafer were represented by an ASCII file that included a representation of all of the mass spectrums (for example—201(1)-201(24)) obtained during the whole RGA process of that wafer. It is noted that each file can be regarded as including relevant WAP information. The sampling, logarithmically scaling and quantization can be regarded as processing the WAP information. The processing can be implemented by WAP information processor 45.

Files relating to one hundred and seventy wafers were used to generate a classifier. Files relating to the remaining forty one wafers were sent to the classifier in order to evaluate the classifier.

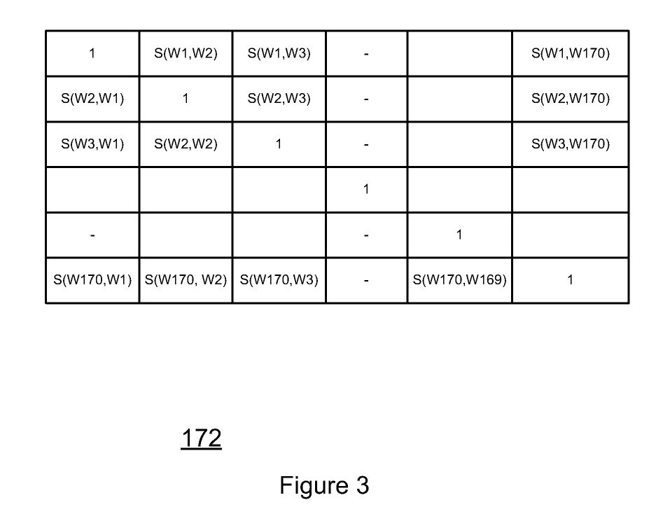

The ASCII files of the one hundred and seventy wafers were sent to compression based similarity module 42. Compression based similarity module 42 calculated compression based similarity results representative of the similarity between each pair of wafers out of these 170 wafers. FIG. 3 illustrates a 170×170 matrix 211 that included the compression based similarity results for these wafers. A compression based similarity result between a first wafer (Wa) to a second wafer (Wb) is denoted in FIG. 3 as S(Wa, Wb). Accordingly, S(W1,W2) is a compression based similarity between wafer W1 and wafer W2.

Matrix 211 (or other representation of the compression based similarities between each pair of wafer out of these one hundred and seventy wafers) was sent to classifier generation module 43. Classifier generation module 43 also received functionality information relating to these one hundred and seventy wafers and in response generated classifier 44.

After classifier 44 was generated compression based similarity module 42 was fed

with ASCII files of each wafer out of the remaining forty one wafers.

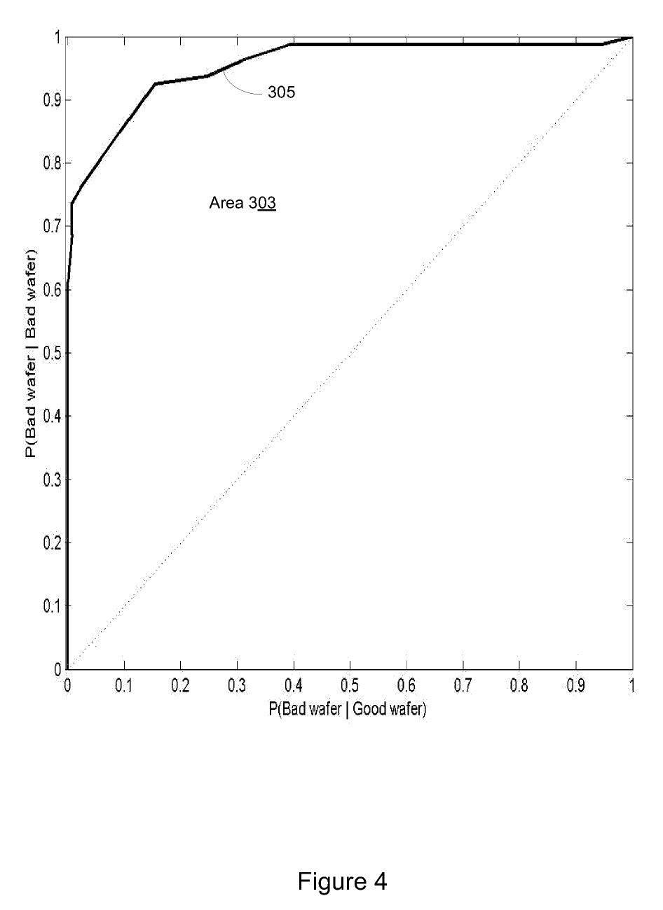

Compression based similarity module 42 calculated compression based similarity results representative of the similarity between each pair of wafer out of these forty one wafers. These results as well as functionality information of each of the forty one wafers were fed to classifier generation module 43 in order to evaluate classifier 43. The evaluation process generated ROC curve 305 of FIG. 4. The area (303) under ROC curve 305 was about 0.95.

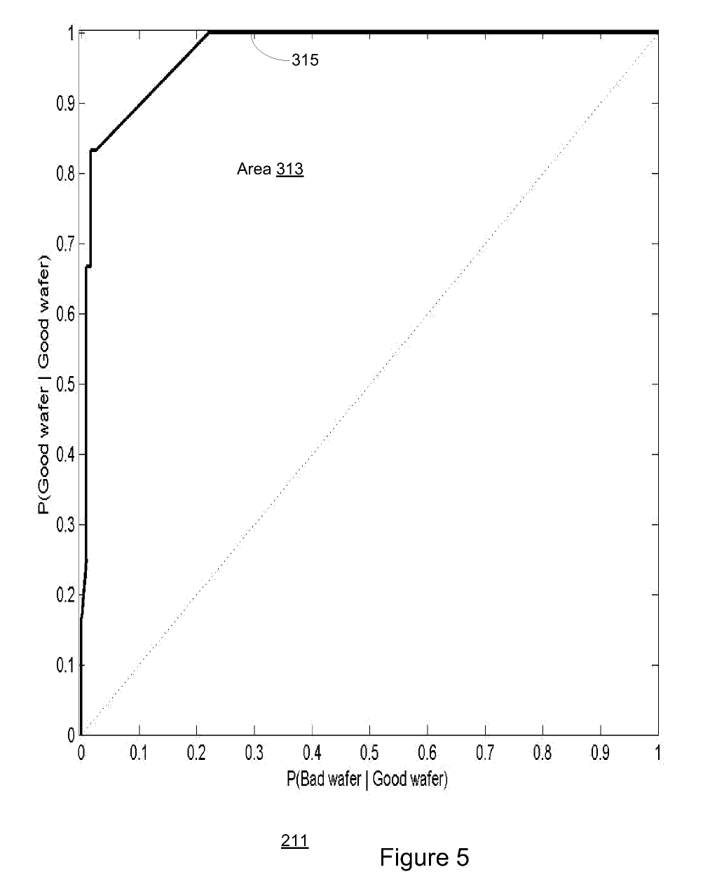

A second group of wafers included one hundred and thirty five wafers out of which twelve wafers were defective. Applying the mentioned above processes resulted in a classifier that was characterized by ROC curve 315 of FIG. 5. The area (313) under ROC curve 315 was about 0.97.

According to another embodiment of the invention system 40 can process portions of WAP information in order to determine which stage in the manufacturing process caused the WAP abnormality. Thus, instead of viewing the WAP as a whole, it can be viewed as a combination of independently analyzed WAP stages.

It is assumed that WAP abnormalities cause WAP information of different wafers to differ from each other. Thus, root cause analysis can be facilitated by comparing WAP information relating to different WAP stages. Root cause analysis can be facilitated by comparing WAP information obtained during one or more test, review, analysis or inspection stages.

A sample root cause analysis can include analyzing only few mass spectrums out of a larger group of mass spectrums obtained during a RGA process or analyzing sub-sets of mass spectrums obtained during the RGA process. For example, instead of selecting as WAP information the whole mass spectrums, only a portion of the mass spectrum can be selected to provide relevant WAP information.

Thus, instead of generating an ASCII file that includes a representation of all the mass spectrums obtained during the whole RGA process, files that represent one or few mass spectrums (or portions thereof) are generated and then fed to compression based similarity module 43.

FIG. 6 illustrates relevant WAP information selected during different iterations of a progressive WAP abnormalities detection process. Each iteration can involve selecting relevant WAP information that differs from the relevant WAP information that was selected during a previous iteration of the progressive WAP abnormalities detection process. For example, during a first iteration of the progressive WAP abnormalities detection process the relevant WAP information (RI(I1) 222(1)) includes the first mass spectrum of each wafer (collectively denoted “first RGA scan 220(1)).

A j'th iteration can include selecting the first till j'th mass spectrums of each wafer to provide the relevant WAP information of the j'th iteration. For example, during the second iteration the relevant WAP information (RI(I2) 222(2)) includes the first mass spectrum of each wafer (first RGA scan 220(1)) and the second mass spectrum of each wafer (second RGA scan 220(2)). During the twenty fifth iteration the relevant WAP information (RI(I25) 222(25)) includes the first mass spectrum of each wafer (first RGA scan 220(1)) till the twenty fifth mass spectrum of each wafer (twenty fifth RGA scan 220 (25)) or less, if a wafer was scanned less than 25 times.

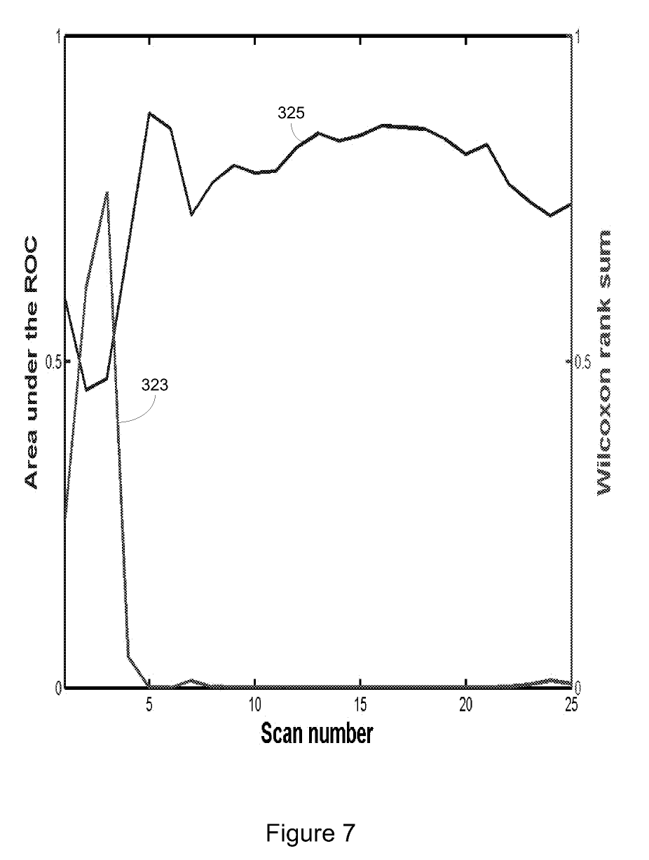

FIG. 7 illustrates the areas between ROC curves obtained during each of the mentioned above iteration. Area under the ROC curve 325 indicates that WAP abnormalities can be detected by analyzing a combination of the first till fifth mass spectrums of each wafer.

Yet for another example, WAP information can include timing information obtained during multiple stages of a WAP. The timing information can indicate how long a wafer was positioned within each chamber (in chamber period) and how long a wafer was maintained outside a chamber (out of chamber period). Typically, maintaining a wafer within a chamber for a period that differs from a desired period can be regarded as a manufacturing process abnormality. It can cause wafer failures.

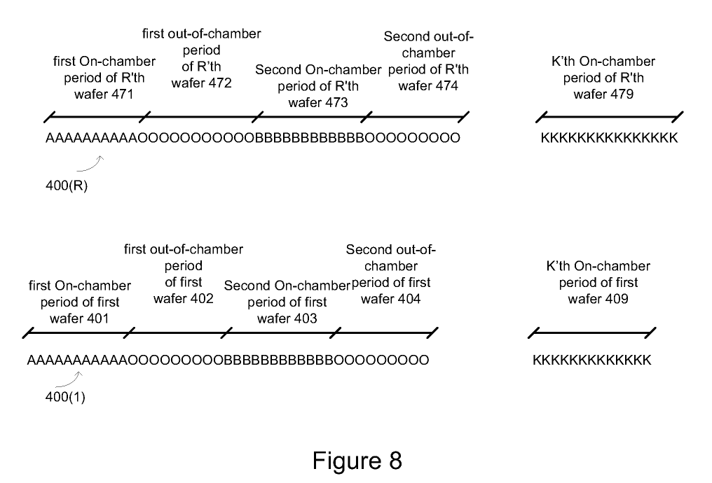

FIG. 8 illustrates a conversion of timing information to relevant WAP information according to an embodiment of the invention.

Timing information is converted to a sequence of ASCII characters, one ASCII character (for example the ASCII character representative of the letter ‘O’) can represent out-of-chamber periods while different ASCII characters represent different in-chamber periods.

First sequence 400(1) includes the following string of letters: “AAAAAAAAAAAOOOOOOOOOBBBBBBBBBBBBOOOOOOOOO KKKKKKKKKKKKK”. Each letter out of letters A till K represents an in-chamber period associated with the first (A'th) chamber till the K'th chamber respectively. This sequence is converted to an ASCII file that is sent to compression based similarity module 42.

First sequence 400(1) represents K in-chamber periods and (K-1) out-of-chamber periods that occurred during the manufacturing process of a first wafer.

Referring to FIG. 8, the in-chamber periods include first in-chamber period of first wafer 401 and second in-chamber period of first wafer 401 till K'th in-chamber period of first wafer 409. Out-of-chamber periods include first out-of-chamber period of first wafer 402 and second out-of-chamber period of first wafer 404 till (K-1)'th in-chamber period of first wafer.

Another sequence (denoted 400(R)) includes the following string of letters: “AAAAAAAAAAOOOOOOOOOOOBBBBBBBBBBBBOOOOOOOOO . . . KKKKKKKKKKKKKKK”.

Sequence 400(R) represents K in-chamber periods and (K-1) out-of-chamber periods that occurred during the manufacturing process of the R'th wafer. R being a positive integer. Referring to FIG. 8, the in-chamber periods include first in-chamber period of R'th wafer 471 and second in-chamber period of R'th wafer 471 till K'th in-chamber period of R'th wafer 479. Out-of-chamber periods include first out-of-chamber period of R'th wafer 472, second out-of-chamber period of R'th wafer 474 till (K-1)'th in-chamber period of R'th wafer.

It is noted that the generation of the ASCII files can be executed by WAP information processor 45.

FIG. 9 illustrates ROC curve 333 of a classifier obtained using the mentioned above ASCII files and ROC curve 335 of another classifier obtained without the format conversion.

FIG. 10 illustrates method 100 for WAP abnormalities detection according to an embodiment of the invention.

Method 100 can be executed by system 40 but this is not necessarily so.

Method 100 starts by stage 110 of retrieving WAP information.

Stage 110 is followed by either one or optional stage 120 and 130 or a combination of both. FIG. 10 illustrates method 100 as including both stages but this is not necessarily so.

The outcome of these one or more optional stages is termed relevant WAP information. The term “relevant” indicates that the information is utilized in further stages of method 100.

Stage 120 includes selecting a portion of the WAP information in order to provide relevant WAP information.

Stage 130 includes processing relevant WAP information.

Stages 120 and 130 are followed by stage 140 of generating a classifier in response to compression based similarities between relevant WAP information relating to different wafers.

Stage 140 includes: (i) stage 142 of compressing relevant WAP information, (ii) stage 144 of generating compression based similarity results, and (iii) stage 146 of generating a classifier in response to the compression based similarity results and additional information (such as functional information).

FIG. 10 also illustrates stage 140 as including stage 148 of evaluating the classifier. The evaluation can assist in determining whether the classifier is good enough, whether there is a need to update an existing classifier and the like. Multiple iterations of stage 142-148 can be executed until a satisfactory classifier is provided.

Stage 140 is followed by stage 150 of utilizing the classifier to detect WAP abnormalities. Stage 150 is conveniently applied on relevant WAP information that was not used to generate the classifier during stage 140. Typically, stage 150 is executed without receiving functional information. Rather, the classifier is expected to classify wafers to defective or functional wafers.

Stage 150 can include stage 152 of compressing relevant WAP information, stage 154 of generating compression based similarity results, and stage 156 of classifying wafers in response to compression based similarity results.

It can be convenient to analyze not the whole WAP information as a whole but rather portions of the WAP information. For example, a root cause analysis can try to determine when a manufacturing abnormality occurred. Root cause analysis can analyze portions of integrated classification information.

According to an embodiment of the invention multiple repetitions of stages 110-150 can be executed. The different iterations can differ from each other by the selection of different portions of WAP information.

Different portions of WAP information are selected to provide different relevant WAP information for each wafer out of multiple wafers. Different classifiers are generated in response to the different relevant WAP information. Classification results of the different classifiers are compared to each other to detect WAP abnormalities.

Conveniently, the selection of different portions can be executed in a progressive manner. Accordingly, multiple iterations of stage 120 include progressively selecting different portions of WAP information to provide different relevant WAP information for each wafer out of multiple wafer.

Furthermore, the invention can take the form of a computer program product accessible from a computer-usable or computer-readable medium providing program code for use by or in connection with a computer or any instruction execution system. For the purposes of this description, a computer-usable or computer readable medium can be any apparatus that can contain, store, communicate, propagate, or transport the program for use by or in connection with the instruction execution system, apparatus, or device.

The medium can be an electronic, magnetic, optical, electromagnetic, infrared, or semiconductor system (or apparatus or device) or a propagation medium. Examples of a computer-readable medium include a semiconductor or solid-state memory, magnetic tape, a removable computer diskette, a random access memory (RAM), a read-only memory (ROM), a rigid magnetic disk and an optical disk. Current examples of optical disks include compact disk-read only memory (CD-ROM), compact disk-read/write (CD-R/W) and DVD.

A data processing system suitable for storing and/or executing program code will include at least one processor coupled directly or indirectly to memory elements through a system bus. The memory elements can include local memory employed during actual execution of the program code, bulk storage, and cache memories which provide temporary storage of at least some program code in order to reduce the number of times code must be retrieved from bulk storage during execution.

Input/output or I/O devices (including but not limited to keyboards, displays, pointing devices, etc.) can be coupled to the system either directly or through intervening I/O controllers.

Network adapters may also be coupled to the system to enable the data processing system to become coupled to other data processing systems or remote printers or storage devices through intervening private or public networks. Modems, cable modem and Ethernet cards are just a few of the currently available types of network adapters.

Variations, modifications, and other implementations of what is described herein will occur to those of ordinary skill in the art without departing from the spirit and the scope of the invention as claimed.

Accordingly, the invention is to be defined not by the preceding illustrative description but instead by the spirit and scope of the following claims.

We claim:

1. A method for wafer manufacturing process abnormalities detection, comprising:
generating a classifier in response to compression based similarities between relevant wafer manufacturing process information of pairs of wafers; and
utilizing the classifier to detect wafer manufacturing process abnormalities.

2. The method according to claim 1 comprising receiving wafer manufacturing process information and selecting a portion of the wafer manufacturing process information to provide the relevant wafer manufacturing process information.

3. The method according to claim 1 comprising selecting different portions of wafer manufacturing process information to provide different relevant wafer manufacturing process information for each wafer out of multiple wafers; generating different classifiers in response to the different relevant wafer manufacturing process information; comparing between classification results of the different classifiers to detect wafer manufacturing process abnormalities.

4. The method according to claim 3 comprising progressively selecting different portions of wafer manufacturing process information to provide different relevant wafer manufacturing process information for each wafer out of multiple wafers.

5. The method according to claim 1 wherein the relevant wafer manufacturing process information comprises mass spectrum information obtained during different phases of a residual gas analysis of the wafer.

6. The method according to claim 1 wherein the relevant wafer manufacturing process information comprises timing information obtained during multiple phases of a wafer manufacturing process.

7. The method according to claim 1 comprising generating relevant wafer manufacturing process information representative of duration of in module periods and duration of out of module periods.

8. The method according to claim 1 wherein the relevant wafer manufacturing process information comprises information selected from a group consisting of: (i) a portion of a mass spectrum obtained during multiple phases of a residual gas analysis of the wafer or (ii) a mass spectrum obtained during a single phase of a residual gas analysis of the wafer.

9. The method according to claim 1 wherein the relevant wafer manufacturing process information comprises a portion of manufacturing timing information obtained during multiples phases of a wafer manufacturing process.

10. The method according to claim 1 comprising detecting wafer manufacturing process abnormalities by applying a non-compression based analysis process.

11. A computer program product comprising a computer usable medium including a computer readable program, wherein the computer readable program when executed on a computer causes the computer to generate a classifier in response to compression based similarities between relevant wafer manufacturing process information of pairs of wafers; and utilize the classifier to detect wafer manufacturing process abnormalities.

12. The computer program product according to claim 11 that causes the computer to receive wafer manufacturing process information and select a portion of the wafer manufacturing process information to provide the relevant wafer manufacturing process information.

13. The computer program product according to claim 11 that causes the computer to select different portions of wafer manufacturing process information to provide different relevant wafer manufacturing process information for each wafer out of multiple wafers; generate different classifiers in response to the different relevant wafer manufacturing process information; and compare between classification results of the different classifiers to detect wafer manufacturing process abnormalities.

14. The computer program product according to claim 13 that causes the computer to progressively select different portions of wafer manufacturing process information to provide different relevant wafer manufacturing process information for each wafer out of multiple wafers.

15. The computer program product according to claim 11 wherein the relevant wafer manufacturing process information comprises mass spectrum information obtained during different phases of a residual gas analysis of the wafer.

16. The computer program product according to claim 11 wherein the relevant wafer manufacturing process information comprises timing information obtained during multiple phases of a wafer manufacturing process.

17. The computer program product according to claim 11 that causes the computer to generate relevant wafer manufacturing process information representative of duration of in module periods and duration of out of module periods.

18. The computer program product according to claim 11 wherein the relevant wafer manufacturing process information comprises information selected from a group consisting of: (i) a portion of a mass spectrum obtained during multiple phases of a residual gas analysis of the wafer or (ii) a mass spectrum obtained during a single phase of a residual gas analysis of the wafer.

19. The computer program product according to claim 11 wherein the relevant wafer manufacturing process information comprises a portion of manufacturing timing information obtained during multiples phases of a wafer manufacturing process.

20. The computer program product according to claim 11 that causes the computer to detect wafer manufacturing process abnormalities by applying a non-compression based analysis process.
